(19) United States
(12) Patent Application Publication
(10) Pub. No.: US 2020/0349303 A1
(43) Pub. Date: Nov. 5, 2020

(54) AUTOMATED DESIGN DRAWING ANALYSIS FOR QUOTING AND MANUFACTURING FEEDBACK

(71) Applicant: Fictiv, Inc., San Francisco, CA (US)

(72) Inventor: Gregory Burton, Mountain View, CA (US)

(21) Appl. No.: 16/864,022

(22) Filed: Apr. 30, 2020

Related U.S. Application Data
(60) Provisional application No. 62/841,185, filed on Apr. 30, 2019.

(51) Int. Cl. G06F 30/17; G06F 30/12; G06K 9/62

(52) U.S. Cl. CPC G06F 30/17; G06K 9/6267; G06F 30/12

(57) ABSTRACT

The disclosed embodiments include a method for automatic analysis of design drawings to increase accuracy of quoting and generating manufacturing feedback as part of the manufacturing process of a product or mechanical part. A design drawing depicting a product can be automatically inspected to identify and classify characters included in the design drawing. The classified characters can then be processed by one or more tasks included in a rule engine to modify at least one of a quote or manufacturing feedback relating to the manufacturing process of the product.

### CROSS-REFERENCE TO PRIOR APPLICATIONS

The present application claims benefit to U.S. Provisional Patent Application No. 62/841,185, titled “AUTOMATED DESIGN DRAWING ANALYSIS FOR QUOTING AND MANUFACTURING FEEDBACK,” and filed Apr. 30, 2019, which is incorporated by reference in its entirety hereto.

### BACKGROUND

Various physical products are designed with particular specifications. For example, a mechanical device may include a design with specific dimensions so that the mechanical device functions properly in a system. Designers/engineers may utilize drawings or depictions of the product to capture the specifications of that product. Examples of tools to capture depictions of products can include a digital document in various formats (e.g., in portable document format (PDF), a slideshow format (Microsoft PowerPoint®) or in an electrical image file (e.g., bitmap (BMP), Joint Photographic Experts Group (JPEG)). Another example tool to capture the specifications of a product can include Computer Aided Design (CAD) model files (e.g., standard triangle language (STL), standard for the exchange of product model data (STEP)) produced by various sources, such as Dassault®, Siemens®, etc.

Many designers of physical products work with manufacturers to manufacture the physical products with the particular specifications. Examples of such manufacturers can include machine shops, contractors, contract manufacturers, etc. The manufacturer may inspect design documents (e.g., PDF document, CAD models) to generate a quote to manufacture each of the products for the designer. Based on the acceptance of the quote, the manufacturer manufactures the product at a specified quantity, with each product matching the specifications provided in the design documents.

### BRIEF DESCRIPTION OF THE DRAWINGS

FIG. 1 illustrates a mechanical design drawing, in accordance with various embodiments.

FIG. 2 illustrates an example flowchart to dynamically modify a quote to manufacture a mechanical apparatus from a mechanical design drawing, in accordance with various embodiments.

FIG. 3 is an example flow diagram for processing classified text using a rules engine, in accordance with various embodiments.

FIG. 4 is a block diagram of an example network-accessible server system, in accordance with various embodiments.

FIG. 5 is a flow diagram illustrating a method to generate quotes for manufacturing feedback, in accordance with various embodiments.

FIG. 6 is a block diagram that illustrates an example of a processing system in which at least some operations described herein can be implemented.

The drawings and tables depict various embodiments for illustration only. Those skilled in the art will recognize that alternative embodiments may be employed without departing from the principles of the technology. Accordingly, while specific embodiments are shown in the drawings, the technology is amenable to various modifications.

### DETAILED DESCRIPTION

The disclosed teachings generally relate to manufacturing products. The disclosed teachings more particularly relate to automatic analysis of design drawings to increase an accuracy of quoting and generating manufacturing feedback as part of the manufacturing process of the product.

Various examples of the invention will now be described. The following description provides certain specific details for a thorough understanding and enabling description of these examples. One skilled in the relevant technology will understand, however, that the invention can be practiced without many of these details. Likewise, one skilled in the relevant technology will also understand that the invention can include many other obvious features not described in detail herein. Additionally, some well-known structures or functions may not be shown or described in detail below, to avoid unnecessarily obscuring the relevant descriptions of the various examples.

The terminology used below is to be interpreted in its broadest reasonable manner, even though it is being used in conjunction with a detailed description of certain specific examples of the invention. Indeed, certain terms may even be emphasized below; however, any terminology intended to be interpreted in any restricted manner will be overtly and specifically defined as such in this Detailed Description section.

In many cases, a designer may create a design for a physical product. The physical product may include one or more specifications, such as dimensions, sizes, gradients, features, angles, etc., that identifies various features of the physical product. These specifications may be depicted in a digital design drawing, such as a PDF drawing. In some embodiments, digital model files, such as CAD model files, can describe a 3-dimensional (or “3D”) specification of the physical product.

In many cases, designers of physical products may contact manufacturers (machine shops, contractors, contract manufacturers, etc.) to manufacture the physical product. Manufacturers may provide quotes or estimates that provide estimated details (e.g., a cost or time) to manufacture a desired quantity of the physical product.

Many manufactures can provide quotes/estimates at least partially based on a digital model file, such as a CAD model. Various companies (e.g., Fictiv®, ProtoLabs®, Xometry®) may utilize CAD software (e.g., FeatureCAM®) to provide quotes/estimates to manufacture the physical product. In some embodiments, the quotes/estimates may at least partially be based on design drawings.

However, many specifications for a physical product to be manufactured may be unable to be specified in a digital model or drawing. As an example, many common CAD format standards may not include a way to encode desired “post-process” operations, such as paint, bead blasting, anodization, etc. other specifications are rarely specified in a CAD format, such as tolerances and geometric dimensioning and tolerancing (GD&T). In some embodiments, some specifications may be included only in a CAD drawing, where other specifications are only included in 2-D design drawings, which may account for at least a portion of the line items included in a quote/estimate.

In some embodiments, based on the content of a drawing, a person assisting in the generation of a quote (or a “quoter”) may need to ask clarifying questions, get permission for design modifications, or give feedback as to why certain specifications cannot be met (Design for Manufacturability Feedback). However, communicating clarifying questions or requests for modifications between manufacturer and designer of the physical product may delay the manufacture of the physical product and reduce the efficiency for the manufacturer to manufacture the physical product with a desired accuracy.

### System Overview

The present embodiments relate to a system for automated design drawing analysis for quoting and manufacturing feedback. A mechanical design drawing can be obtained and inspected to derive a depiction of an element, an article of manufacture, or one or more parts of a mechanical apparatus and various characters (e.g., notes, material information, size specifications, callouts) in the mechanical design drawing. The characters may be processed to extract and classify the text patterns. The classified text patterns can be processed using a rules engine to update a quote representing a modification to manufacture a mechanical apparatus taking into account the information included in the classified text patterns and information derived from the rules engine. Thus, the present embodiments assist in the overall creation of an apparatus or individual components thereof, so that while the term “apparatus” is generally used herein, it is intended to include one or more elements, articles, components or parts of a mechanical apparatus to be manufactured.

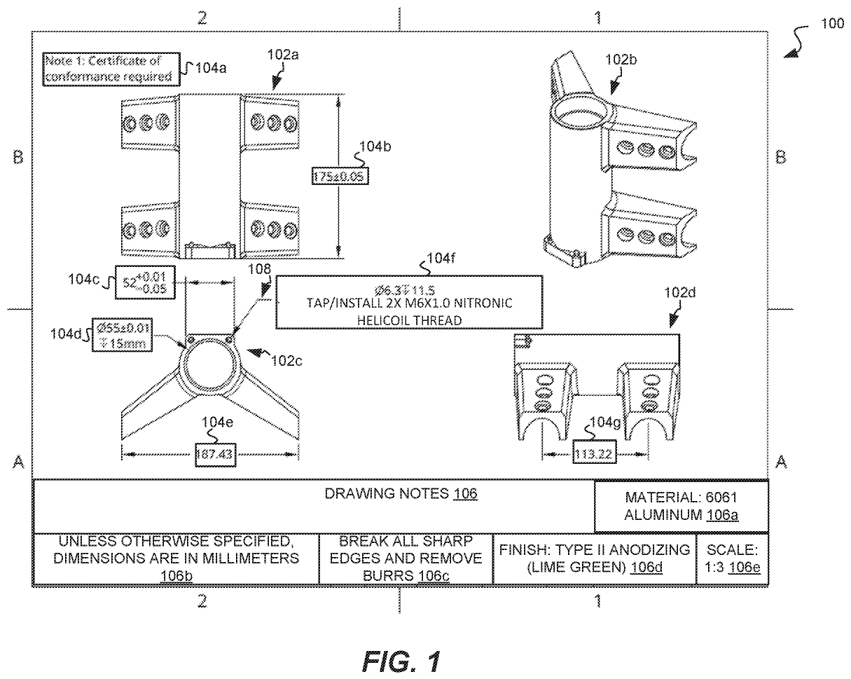

FIG. 1 illustrates a mechanical design drawing 100, in accordance with various embodiments. In this example, in addition to general dimension information, positional and surfaces tolerances may be specified. Other information may be included, such as the part material, drilling operations, tapping, reaming, engraving, and special finishing operations (e.g., material information, Finish: Type II Anodizing (Lime Green)), assembly instructions, fit instructions/specifications, etc.

Also, off-the-shelf components may be specified, either for assembly (e.g., standard bolts and screws), or for “rework,” where machined modifications may be made to standard or catalog parts. This example is not intended to describe a limit to what may be written in design drawing, nor is this the only formatting or layout which may be used.

As noted above, various information (secondary finishing processes, tolerance information, references to off-the-shelf components, etc.) can be written into design drawings that either cannot or may not be encoded into CAD software models and/or file formats. However, in many cases, these specifications can account for a portion of or a majority of the cost of a manufacturing job. This may significantly impact the speed at which a specified quantity of physical products are manufactured, and even impact the feasibility of completing the task of manufacturing the physical product.

As shown in FIG. 1, a mechanical design drawing 100 can include one or more depictions of a portion or part of a mechanical apparatus 102a-d. For instance, various views (e.g., depictions 102a-d) of a mechanical part (e.g., a perspective view, a top view, bottom view) can be provided in a mechanical design drawing 100 that can be used for manufacture of the mechanical part.

Further, the mechanical design drawing 100 can include supplemental information relating to the depictions of the mechanical part 102a-d. The supplemental information can include various specifications, callouts, notes, etc., that further define aspects of the mechanical part. The supplemental information can be provided along with indicators, such as arrows or brackets, indicating a portion of a depiction of a mechanical part that the supplemental information applies.

As an example, supplemental information can include a note 104a indicating that a certification of conformance is required for manufacturing a mechanical part. As another example, supplemental information can include dimension and tolerance information 104b providing a length of a portion of the mechanical part and a tolerance in which the length can vary. The supplemental information can also include angle, pitch, depth information, for example. As another example, the supplemental information can include manufacturing notes, such as a note 104f to tap/install 2×M6×1.0 Nitronix Helicoil Thread to an identified portion as depicted in a third depiction of a mechanical part 102c.

In some instances, supplemental information can be provided as drawing notes 106. Drawing notes 106 can include a series or set of information relating to the manufacture and finish of a mechanical part, such as, for example, size information, finish information, colors, materials, etc. As an example, the drawing notes 106 can include material information 106a (e.g., Material: 6061 aluminum), dimension information 106b (e.g., “Unless otherwise specified, dimensions are in millimeters”), finish information 106c (“Break all sharp edges and remove burrs”), finish color information 106d (e.g., Finish: type II anodizing (lime green)), scale information 106e (e.g., Scale: 1:3), etc.

As shown in FIG. 1, the supplemental information can include an indicator (e.g., arrow 108). The indicator can include an arrow, line, bracket, etc., indicating a part of a depiction of a mechanical part that corresponds to the supplemental information. In some instances, a location of the supplemental information can be indication of what portion of a mechanical design drawing the information relates. A coordinate system can be utilized to determine a proximity of supplemental information and/or an indicator to a particular depiction of a mechanical part. The location information can be used to efficiently correlate supplemental information to a corresponding portion of a depiction of a mechanical part.

As noted above, the present embodiments relate to a system for automatically extracting various information from a design drawing for a physical product and assisting in the generation of quotes/estimates to manufacture a quantity of the physical product. In some embodiments, the present embodiments relate to a system to automatically extract information from design drawings to automate the generation of quotes/estimations. Automatically extracting information directly from design drawings may improve the accuracy of generating quotes manually as well as improving the accuracy of automatically generated quotes with design feedback.

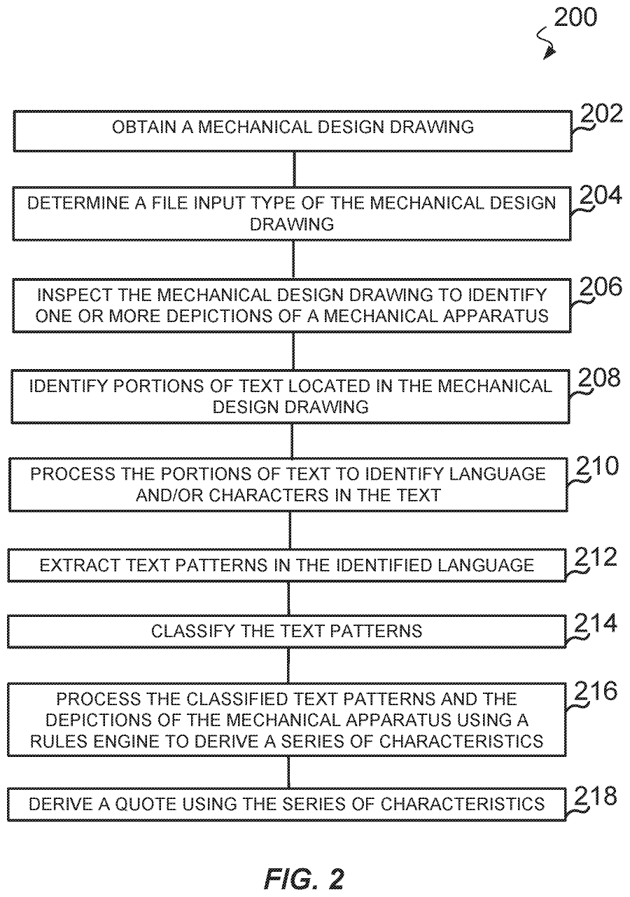

FIG. 2 illustrates an example flowchart 200 implemented by the present system to dynamically modify a quote to manufacture a mechanical part from a mechanical design drawing, in accordance with various embodiments. As shown in FIG. 2, dynamically modifying a quote to manufacture a mechanical part from a mechanical design drawing begins with the system obtaining the mechanical design drawing (block 202).

As noted above, the mechanical design drawing can include a depiction of mechanical part and supplemental information. The mechanical design drawing can comprise any of a variety of file types, each file type including different characteristics and data. Accordingly, the system determines a file input type of the mechanical design drawing (block 204). This can include comparing a file type identifier (e.g., a file type extension) of the mechanical design drawing. Based on the determined file type, the mechanical design drawing can be processed. In some cases, the mechanical design drawing can be converted from a first file type to another file type for efficiency in processing the mechanical design drawing.

Example formats for a digital document may include PDF, PowerPoint, BMP, PNG, JPEG, etc. The digital document can be sent from a user computing device and sent directly over any network to a server computer executing the functions described below. Alternatively or additionally, a user computer can upload the digital documents to cloud storage or to a cloud computing system that either executes the functions described below or that in turn provides access to the digital documents by the server computer.

In some embodiments, the mechanical design drawing may be electronically transmitted to an electronic device associated with a product manufacturer or quoter, such as a computer, server, network-accessible server system, etc. As an example, an electronic device associated with a designer of a physical product may transmit a design drawing to a server associated with a quoter via a network (e.g., the internet).

The present system can inspect the mechanical design drawing to identify one or more depictions of the same mechanical part (block 206). Identifying depictions of a mechanical part can include processing the mechanical design drawing that includes details that are indicative of a mechanical part, such as, for example, a threshold number of connecting design lines or a design greater than a threshold size on the mechanical design drawing. In some instances, identifying one or more depictions of a mechanical part can include using position information or coordinate information on the mechanical design drawing to identify positions on the mechanical design drawing that includes a depiction of a mechanical part.

The system processes the mechanical design drawing to identify portions of text included in the mechanical design drawing (block 208). Portions of text can include any combination of text, characters, symbols, numbers, etc. For example, a portion of text can include a symbol indicative of a desired angle of a portion of a mechanical part followed by a number indicative of a degree that the desired angle is to comprise. The system can process the identified text to identify language and/or characters in the text (block 210). Any suitable character/text recognition process (e.g., optical character recognition (OCR)) can be used to identify text in the mechanical design drawing. In some instances, this can include identifying indicators (e.g., arrows, brackets) associated with the portions of text. The indicators can indicate a corresponding part of the depiction of the mechanical part that the text relates.

The design drawing may include text and graphical geometric information that can be extracted by Optical Character Recognition software (OCR) and/or by extracting the text encodings embedded in the file format as, for example, ASCII or Unicode. The system can extract text included in the design drawing that represents specifications for the mechanical physical product.

As an example, the design drawing (e.g., drawing in FIG. 1) may include a size specification for a tap hole included in a staking tool. In some embodiments, the location of text relating to a measurement may be determined using OCR or from embedded ASCII or Unicode text. Matching text relating to a measurement to a corresponding feature by utilizing the extracted text in conjunction with analysis of the CAD file (e.g., the STEP model). in this case, hole diameters, edge lengths, etc. specified in the CAD file can be correlated with the extracted text.

The system processes identified text to extract text patterns from the identified text (block 212). Text patterns can include a related series of characters that represent an instruction or specification of the mechanical part. This can include identifying characters within a threshold proximity to one another, for example. The system extracted text patterns can be classified into various classifications based on the information included in the extracted text patterns (block 214).

Classifications can be based on information included in the text patterns. For example, a classification can be based on a material type, a finish type, finish instructions, a size specification, etc. In some embodiments, text can be processed via a classification model to derive a classification that corresponds to the extracted text. The classified text patterns can be utilized in identifying relevant rules in a rules engine to derive characteristics to modify a quote to manufacture the mechanical part. In some instances, the quote to manufacture the mechanical part and/or the rules included in the rules engine can be specific to a manufacturer.

The system processes the classified text and the depictions of the mechanical part using a rules engine to derive a series of characteristics (block 216). The rules engine can include a set of rules that, when applied to the information in the mechanical design drawing, modify a quote. For example, a classified text pattern (e.g., an identified material for the mechanical part) can be compared with the rules of the rules engine to identify a rule that indicates that a quote is to be modified based on identifying that the material is to be used for the mechanical part. The updated value identified from the rule can be added to the quote.

The system derives a quote using the series of characteristics derived from the rules engine (block 218). A quote can include a value (or “cost”) associated with manufacturing a mechanical part. The quote value can be first derived to manufacture the mechanical part and then modified based on updated values from the rules engine to update the quote value.

As an example, there are standards and recommendations for the range of diameters one could use to drill a hole before tapping/threading that hole to a standard (e.g., a ¼″-20 tap should be made from a cylindrical hole in the range of 0.201″-0.219″). If it is detected that the text contains a callout for a ¼-20″ tap, data of the CAD file can be searched for holes within the range recommended for ¼-20″ taps, where the identified holes are counted. The count may be used to add labor costs, add line items for purchasing tapping tools, etc. If, for instance, the count was zero, the system could return a warning to the customer or to internal personnel that the CAD models do not appear to be within specifications for the requested tap size.

In some embodiments, matching text relating to a measurement to a corresponding feature may include matching computer graphic renderings of a 3D model with images in the design drawing using a CAD file. Design drawings may be created by generating computer graphic renderings of the 3D model from a standard set of orientations. The known positions of the extracted text on the page could be correlated with the known positions of features of the CAD model on the page (e.g., tap callout text may refer to the nearest hole of the appropriate size). However, it is very common for design drawings to just contain text such as “5×¼-20″” placed arbitrarily on the design drawings, where the author of the drawing is expecting their note to mean “I have five holes that I want tapped with a ¼-20″ tap tool, you can identify them from the hole diameters in my design drawing/CAD file.”

The extracted text and/or graphical geometric information may be extracted and classified via various techniques, such as Regular Expressions (REGEX), dictionaries, template matching, etc. Extraction techniques may differ based on the design drawings, as many design drawings incorporate various techniques in authoring the drawings. In many cases, the text meaning may be assumed by the layout of the drawing (e.g., there may be measurement placed spatially near to a feature being described). In other cases, there may be a set of boxed areas (e.g., in the right-hand corner of the drawing), where particular note(s) may be identified. Classification can be done based on the specification type, where the regular expression describes the specification and/or variations of the specification that may be used to simultaneously detect and classify the text. However, many post-processing requests in the design drawings may include consideration of a spatial arrangement of text. For example, floating text in the design drawing may include:

Finish:

Break all Sharp Edges

Black Anodize

The author of the design drawing may expect that all text below “Finish:” to be included in a list of post-machining finishing work. The positioning and propinquity may be included as part of the classification of the text.

The extracted text can be classified and categorized, and further actions can be automatically performed based on the extracted text. For example, additional line items can be added to the user's quote, warnings and/or requests for confirmation can be displayed to the user, lead times for fulfillment can be adjusted, special notes for Quality Control might be added to the order, and human individuals or automated systems can be signaled to provide or queue additional services related to the order or its fulfillment.

As a first example, Anodization may be a post process service, but it may be a separate line item in the order that has an associated fee and impact on lead time and Quality Control. When the system detects and classifies an “Anodization” callout (e.g., the drawing contains the text “Black Anodize” or “Type II Anodize” etc.) the system may check the customers configuration for their order. If anodization is not already a line item on the order, then it may be added and the total cost, lead time, etc., may be adjusted accordingly.

As another example, a “Helicoil” tap insert may include pieces of hardware made of a hard metal that can be inserted into an oversized tapped hole. Generally, these are requested when the part material is relatively soft (e.g., plastic or aluminum) and there is a risk that threads in the soft material could become damaged or wear out. Special tapping tools, as well as the Helicoil insert products themselves, may be purchased to manufacture the design, so they may be added as extra line items. When the system finds text matching the Helicoil tap regular expression (i.e., a specification for classifying Helicoil tap callouts) the system may attempt to count the number of holes requiring the specified Helicoil taps by correlating the hole diameters found in the corresponding CAD file to the Helicoil's tables for recommended hole sizes. The system may add the cost of the tapping tool as a line item on the order, as well as the count of required tap inserts per part and the requested quantity in the order to add boxes of tap insert hardware as another line item on the order. Also, labor fees for tapping and hardware insertion may be added.

As an example, the regular expression illustrated below (written in Python language's “verbose” regular expression format) could be used to extract “imperial” tap hole annotations from text, e.g., ¼″×20 Helicoil.

| | |
|---|---|
| imperial_regex = ur’” | #Match imperial thread names |

| | |
|---|---|
| (\hat{ }\|[\r\n\s]) | #Starts with newline, whitespace, or beginning of a string |
| [#]? | #Maybe the # symbol, like in #1 |

| | |
|---|---|
| (?P<diameter> | #Capture the diameter |

| | |
|---|---|
| ([0-9]{1,3}([\/][1-9][0-9]*)?) | #Capture an integer, |

including 0, or a fraction, e.g. ¼

| | |
|---|---|
| \| | #Or |

| | |
|---|---|
| ([1-9]{0,3}[.][0-9]*) | #Capture a limited kind of floating |

point number
)

| | |
|---|---|
| ([\”]\|in\|inch)? | #Maybe an inch notation |

| ( | #NPS-type threads do not necessarily have pitch | |
|---|---|---|
| | [ ]? | #Maybe a space |
| | [-x] | # - or x |
| | [ ]? | #Maybe a space |

| | |
|---|---|
| (?P<pitch>[1-9][0-9]{1,2}) | #Capture thread pitch, Number 10- |

999
)?
(

| | |
|---|---|
| [ ]? | #Maybe a space |

(?P<pipe>NPT|NPS[M]?) #Check for a National Pipe

standard
)?

| | |
|---|---|
| [ ]? | #Maybe a space |

(UNC)?[ ]?

| | |
|---|---|
| (?P<helicoil>hc\|helicoil\|sti)? | #Maybe a helicoil callout |

| | |
|---|---|
| [\s\n\r] | #Trailing whitespace or newline |

’”

Based on the extracted and classified information, the rule engine can perform further actions based on the content and categorization of the extracted text. The system may detect, evaluate, and/or categorize dimensional tolerance callouts of one or more types.

Illustrated below is an example “one sided tolerance” regular expression. This tolerance may tend to be drawn in positions either above and/or below a nominal dimension, like superscript or subscript except for the font size generally not changing, to denote the upper and lower bounds on an error from the nominal. As an example, a nominal value for the diameter of a hole might have a −0.000″ offset downward by half of a font size, and a +0.003″ offset upward by half of a font size, to denote that the measured value for the hole is not less than the nominal value, but may exceed the nominal value by as much as 0.003″.

#Identify things like −.01mm, the one-sided tolerances

| (\hat{ }\|[\s]) | #Starts with the beginning of a string or whitespace | |
|---|---|---|
| (?P<sign>[+−]) | | #Plus or a minus |

| | |
|---|---|
| [ ]? | #Maybe a space |

(?P<value>[1-9]+|[0-9]*([.][0-9]*)) #An integer or a floating point number

| [ ]? | #Maybe a space | |
|---|---|---|
| (?P<unit>°\|mm\|in\|inch)? | | #Maybe a unit |

| | |
|---|---|
| (?=[\s$]) | #Look ahead for trailing whitespace or end of string |

There may also be dimensional tolerances that may simply identify that a nominal value can vary high or low by the same amount, i.e. X+/−Y. Below is an example regular expression for detecting and classifying the tolerance portion.

#Identify things like +/−.01mm
([±]|[+][ ]?[\/] [ ]?[−]) # plusminus symbol, or some variation on +/−
(
[ ]?

| | |
|---|---|
| (?P<value>[1-9]+\|[0-9]*([.][0-9]*)) | # integer or float |

)
[ ]?

| | |
|---|---|
| (?P<unit>°\|mm\|MILLIMETER[S]?\|in\|inch)? | # unit annotation |

As an example, in the ¼″×20 Helicoil example as illustrated above, a quote can be adjusted to account for labor hours machining the tap feature, and for the purchase and installation of the “Helicoil” off-the-shelf component. The quoted price could be modified, and the lead time could be adjusted. The user could also be notified that these actions would be taken because of the detected text in their document(s). A note could be automatically added to the inspection list of a Quality Control team to verify that the feature was manufactured and installed.

In some embodiments, a database may be referenced to identify specific information, such as a cost per box of Helicoil insert hardware of a given size, for example. In other embodiments, a classification of the text may be referenced. As an example, “Bead Blasting” may be currently classified as “special finishing” processes, as there may not be a rule to automatically compute the cost of that service. In this example, a representative may be contacted by the system and is instructed to call the service vendor for a quote for the service. The system may also transmit a message to a customer information them that a line item may be added to the quote for the requested finishing services, and a number may be added shortly thereafter. The system may identify that a line item may need to be added, but it may not be able to populate all of the information for the line item itself.

The rule engine can inspect the extracted text from the design drawings and performs one or more tasks based on the extracted text. Examples of such tasks include adjusting a cost of a line item in a quote, adjusting a payout to a vendor, adjusting a lead time guarantee, generating a prompt for more information, generating a prompt for an adjustment to the design, generating a prompt for a go/no-go decision from a designer of the product, rejecting the order, and generating instructions for fulfillment verification (quality control).

The present embodiments can process one or more design drawings much faster than a speed at which a human could process the same content. A computer system such as that described here can extract all of the pertinent information from a design drawing in seconds or fractions of a second. By contrast, evaluation by a human quoting expert may include time to react to a user's request, open a document, read the document, and take corresponding action. The time to perform these steps can include around 5-10 minutes, but in many cases can average closer to 20 minutes with service level agreements to customers taking around 60 minutes. Some services or machine shops may take even longer to review. Accordingly, the present embodiments can process design drawings with minimal or no user involvement in a shorter time than a time to manually process the drawings.

### Rules Engine Overview

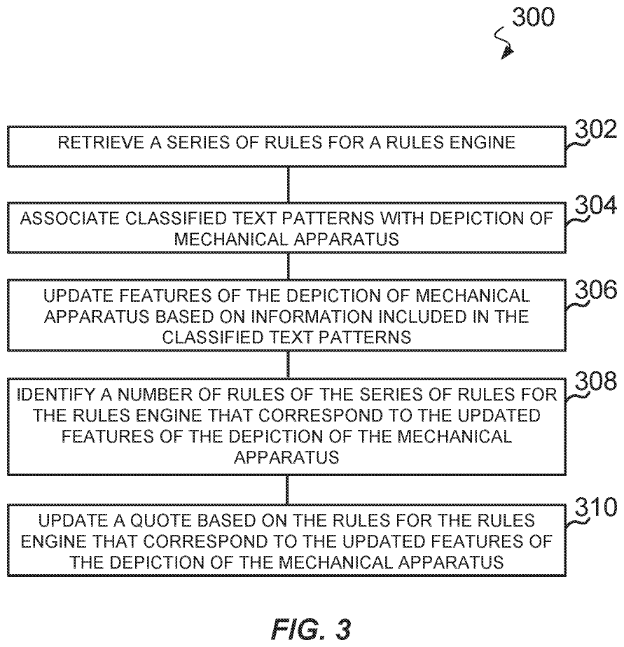

FIG. 3 is an example flow diagram 300 for processing classified text using a rules engine, in accordance with various embodiments. Initially, the system retrieves a series of rules for the rules engine (block 302). The rules engine can include the series of rules that are specific to a manufacturer or client. Each rule can be indicative of a modification to a quote. In some embodiments, the rules engine can include a model that processes classified text to derive corresponding rules and to modify the quote.

The rules engine of the system associates the classified text patterns with the depiction of mechanical part (block 304). In other words, a text pattern can be identified as corresponding with a particular feature or part of a mechanical part. This can include identifying an indicator (e.g., an arrow) and matching the indicator to a depiction of a mechanical part or a part or the mechanical part.

The rules engine updates features of the depiction of the mechanical part based on information included in the classified text patterns (block 306). This can include modifying parts of a depiction of a mechanical part based on the classified text patterns. For example, if a classified text pattern is a length of a part of a mechanical part, the mechanical part can be updated to include a length that corresponds to the classified text pattern.

The rules engine can process classified text patterns and/or the depictions of the mechanical part to derive a number of rules that correspond to the updated features of the depiction of the mechanical part (block 308). In some instances, each rule can be associated with a specific classification, and all rules associated with the classification of the classified text pattern can be compared to identify rules that correspond to the classified text pattern. The rules can be associated with conditions that, when met, instruct the rules engine to apply the rule to the classified text pattern.

As an example, a classified text pattern indicates that a mechanical part includes a first material. This can be compared with a series of rules to identify a rule that provides a value to manufacture a mechanical part when the material includes the first material. In such an example, the rules engine can output a value to manufacture the mechanical part using the first material that can be used to update the quote. For example, a quote for manufacturing mechanical part in stainless steel or titanium can be less than a quote for manufacturing the same part in aluminum.

The rules engine can modify a quote based on the rules for the rules engine that correspond to the updated features of the depiction of the mechanical part (block 310). The quote can be dynamically modified for each classified text pattern or feature of the depictions of the mechanical part that corresponds to rules in the rules engine.

### Network-Accessible Server System Overview

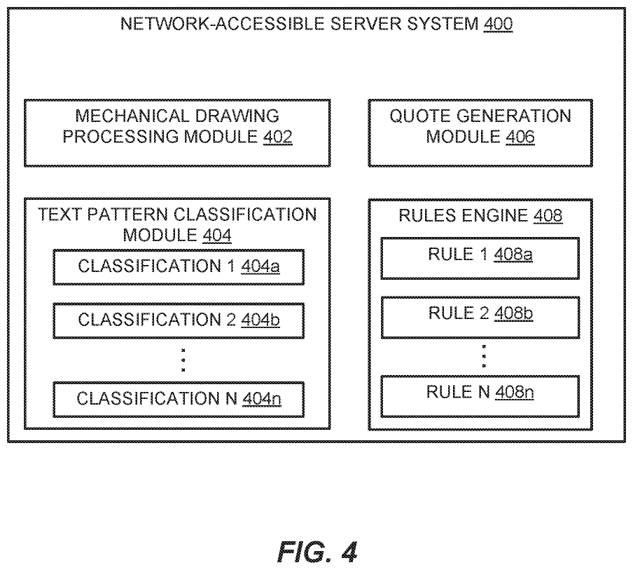

FIG. 4 is a block diagram of an example network-accessible server system 400, in accordance with various embodiments. A network-accessible server system 400 can include one or more interconnected computing nodes (e.g., computers, servers) capable of transmitting and maintaining information among computing nodes. In some cases, the network-accessible server system 400 can include a cloud computing system performing processing tasks across multiple computing nodes. The network-accessible server system 400 can communicate with various devices via a communication interface. For instance, network-accessible server system 400 can receive a mechanical design drawing from a client device (e.g., a computer, laptop, tablet). While a network-accessible server system 400 is used as an example, any computing device or series of devices can be implemented as described herein.

The network-accessible server system 400 can include a mechanical drawing processing module 402. The mechanical drawing processing module 402 can obtain a mechanical design drawing. The mechanical design drawing can be processed using mechanical drawing processing module 402 to detect one or more depictions of a mechanical part. This can include identifying lines/features in the mechanical design drawing indicative of a mechanical part.

The mechanical drawing processing module 402 an also identify a series of supplemental information in the mechanical design drawing. Supplemental information can include information further describing or specifying features of the mechanical part. Identifying the supplemental information can include using a character recognition technique to identify characters in the mechanical design drawing. The mechanical drawing processing module 402 can correlate portions of text to a depiction of a mechanical part or a specific part of a depiction of a mechanical part. For instance, the mechanical drawing processing module 402 can identify an arrow or bracket indicating a specification of a mechanical part and correlate supplemental information to a depiction of a mechanical part based on the indicator.

In some embodiments, the mechanical drawing processing module 402 can populate a database/table/etc. with information indicative of the depictions of the mechanical part and the supplemental information. For instance, upon detecting supplemental information, the supplemental information can be populated in a table as being associated with a corresponding part of a mechanical part. A populated database/table can be used to efficiently process data and derive an updated quote to manufacture the mechanical part.

The network-accessible server system 400 can include a text pattern classification module 404. The text pattern classification module 404 can identify, extract, and classify text in the mechanical design drawing. For instance, the text pattern classification module 404 can use a suitable text recognition technique to identify a type of text included in a text pattern. Example types of text can include text of a given language, a number, a character, a symbol, etc. The text pattern classification module 404 can also identify strings of characters in a text pattern. For instance, if a text string is “34 degrees,” the combination of text types can identify a number and a word, which can be used to identify information being identified in the text string. In some embodiments, upon identifying a symbol, the text pattern classification module 404 can identify a meaning/definition of a symbol by comparing the symbol with a repository of known symbols. For example, the symbol “Ø” can be compared with a repository to determine that the symbol is indicative of a diameter in a mechanical design drawing.

The text pattern classification module 404 can extract text patterns and classify the text patterns. The text pattern can be compared against a series of classifications 404a-n to derive a corresponding classification for the text pattern. Classifications can be based on a type of information represented in the text pattern, for example. The classified text patterns can increase efficiency in processing the text patterns via the rules engine 408.

The network-accessible server system 400 can include a rules engine 408. The rules engine 408 can process classified text patterns to identify a series of characteristics to be used in updating a quote. The rules engine 408 can include a series of rules 408a-n that can be applied to classify text patterns to update a quote. In some instances, a model can be generated via the rules engine 408 that allows for inspection of a text pattern and identification of rules that apply to the text pattern. The classified text pattern may be compared against the rules 408a-n that correspond to the identified classification 404a-n of the text pattern. The rules 408a-n can provide a value to modify a quote based on the classified text pattern. For instance, a rule that applies to a text pattern can indicate that the quote value is to be increased by a specific amount. The rules engine 408 can aggregate the modifications to a quote value and provide the modifications to the quote generation module 406.

The quote generation module 406 can generate a quote to manufacture a mechanical part. For instance, the quote generation module 406 can obtain information about a depiction of a mechanical part and estimate a value to manufacture a number of instances of the mechanical part. The quote generation module 406 can utilize manufacturer-specific values/information to derive an initial quote value.

The quote generation module 406 can modify the initial quote value based on characteristics provided by the rule engine 408. For instance, a quote value can be increased by a value provided by the rules engine based on a classified text pattern in the mechanical design drawing. The quote value can be provided to a specified user in a report transmitted to a device associated with the user. In some instances, the quote value can be detailed in a line-item listing depicting features included in the manufacture of the mechanical part and the modifications to the quote value from the rules engine 408.

### Examples of Extractable Information and Corresponding Actions

As a first example, threaded hole callouts (imperial, metric, custom, etc.) can be identified. For instance, the example in FIG. 1 can include an “imperial standard” hole callout, and any number of possible actions can be performed. For example, any action listed in FIG. 1 can be performed upon detection of the hole callout.

As another example, scale/unit callouts can be identified. These can describe how to interpret the numerical values in the document (e.g., as inches or millimeters).

As another example, tolerance callouts can be identified. Depending on these callouts, additional costs can need to be added to the quote to account for increased machining time, scrap parts/material, increase lead time, or can make manufacture infeasible.

As another example, finishing processes (e.g., anodization, bead blast, paint, etc.) can be identified. Additional line items, fees, lead time adjustments, and/or prompts to the customer for acknowledgement might be generated.

As another example, International Traffic in Arms Regulations (ITAR), Classified, Defense, Export Controlled, Certificate of Conformance/Compliance etc. (e.g., anodization, bead blast, paint, etc.) information can be identified. These callouts can include data to be transferred to special networks or data storage to fulfill legal requirements. Prompts can be generated to the customer and/or employees or contractors to explain potential ramifications, certifications or lack thereof, secondary actions to fulfill the order, etc. Quoting and fulfillment can be automatically blocked depending on the certifications and authorizations of the quoting party.

As another example, callouts for off-the-shelf components for assembly or “rework,” (e.g., catalog/vendor names, part numbers, SKUs) can be identified. These callouts can lead to the prices being adjusted, lead times to be adjusted (e.g., to order the requested component), human beings or automated systems to be notified to check inventory, etc.

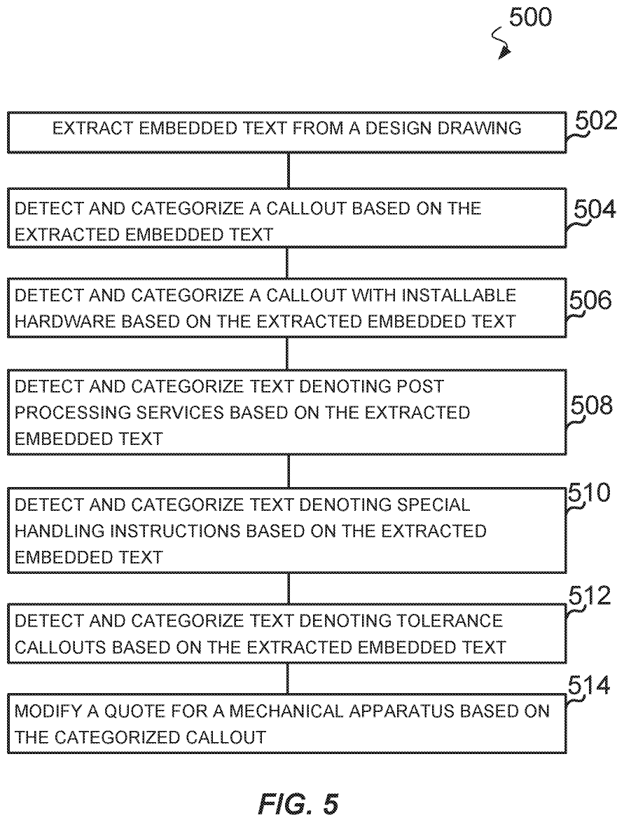

FIG. 5 is a flow diagram illustrating a method 500 to generate quotes for manufacturing feedback, in accordance with various embodiments. The method may include utilizing a technique such as Optical Character Recognition (OCR) to extract embedded text from a mechanical design drawing, which may be referred to as “text extraction” (block 502). This may include other automated analysis of a CAD software file for feature extraction and mechanical process planning from CAD files. Text extraction may be utilized to assist in automatically add or “quote” a part (e.g., to perform a task like add a line item to an order, adjust lead times, provide or solicit written and graphical feedback to a customer, to provide instructions to Quality Control post order, etc.).

The method may include utilizing the text extraction and regular expressions to detect and categorize text in a callout (e.g., the form of a standard “tap callout”) (block 504). The detecting and categorizing text in a callout may include using feature extraction techniques on the data of a CAD file and a database of hole diameters recommended for tap types (tap size tables) to count a number of holes to be tapped with a specified tap.

If a callout does not match a size listed in the database, an alert may be generated and transmitted to the customer and/or company representatives or contractors indicating that the holes in the CAD file are out of spec. In this event, line items may be added to the order for purchase of tapping tools, the lead time may be adjusted to accommodate purchase and delivery of tapping tools, labor fees may be added for tapping based on the counted number of holes, etc.

The method may include detecting and categorizing text in the form of a standard “tap callout” with accompanying installable hardware (e.g., Helicoil tap inserts) using the text extraction and regular expressions (block 506). In this event, line items may be added for the purchase of hardware to be installed, the lead time may be adjusted to accommodate purchase and delivery of installable hardware, etc.

The method may include using text extraction and regular expressions to detect and categorize text denoting post processing and/or finishing services (e.g., anodization, bead blasting, heat treatment, paint, deburring, etc.) (block 508). Using this detection may add service line items to an order or validate that matching services are already line items in the associated order.

The method may include using text extraction and regular expressions to detect and categorize text denoting special information handling restrictions (e.g., classified, ITAR, etc.) (block 510). Using this detection and a database of vendors may limit the possible contractors to send work. Using this detection may trigger sending messages to internal representatives regarding information handling. Using this detection may trigger sending messages to a customer regarding the certifications of the persons receiving the customer's documents.

The method may include using text extraction and regular expressions to detect and categorize text denoting tolerance callouts (block 512). Matching the detected tolerances against a database of tolerance thresholds may assist in deciding if the tolerances can be met, to add services fees and/or labor hours, to trigger sending messages to company representatives or contractors regarding special quality control needs, etc.

The method may include updating or generating a quote for a part of the design drawing based on the detected callout or text (block 514). Updating a quote for a part may include performing a task like adding a line item to an order, adjust lead times, provide or solicit written and graphical feedback to a customer, provide instructions to Quality Control post order, etc. The updated and/or generated quote for the part of the design drawing may facilitate automatic analysis for quoting and manufacturing feedback.

### Example Processing System

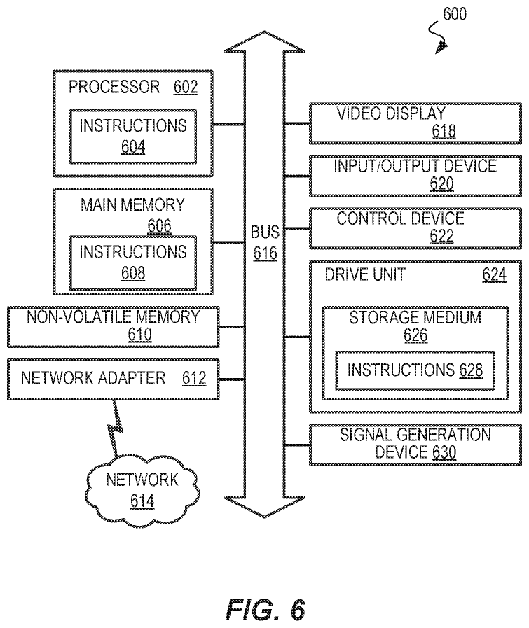

FIG. 6 is a block diagram illustrating an example of a processing system 600 in which at least some operations described herein can be implemented. For example, some components of the processing system 600 can be hosted on an electronic device as described in the present embodiments.

The processing system 600 can include one or more central processing units (“processors”) 602, main memory 606, non-volatile memory 610, network adapter 612 (e.g., network interface), video display 618, input/output devices 620, control device 622 (e.g., keyboard and pointing devices), drive unit 624 including a storage medium 626, and signal generation device 640 that are communicatively connected to a bus 616. The bus 616 is illustrated as an abstraction that represents one or more physical buses and/or point-to-point connections that are connected by appropriate bridges, adapters, or controllers. The bus 616, therefore, can include a system bus, a Peripheral Component Interconnect (PCI) bus or PCI-Express bus, a HyperTransport or industry standard architecture (ISA) bus, a small computer system interface (SCSI) bus, a universal serial bus (USB), IIC (I2C) bus, or an Institute of Electrical and Electronics Engineers (IEEE) standard 1394 bus (i.e., “Firewire”).

The processing system 600 can share a similar computer processor architecture as that of a desktop computer, tablet computer, personal digital assistant (PDA), smartphone, game console, music player, wearable electronic device (e.g., a watch or fitness tracker), network-connected (“smart”) device (e.g., a television or home assistant device), virtual/augmented reality systems (e.g., a head-mounted display), or another electronic device capable of executing a set of instructions (sequential or otherwise) that specify action(s) to be taken by the processing system 600.

While the main memory 606, non-volatile memory 610, and storage medium 626 (also called a “machine-readable medium”) are shown to be a single medium, the term “machine-readable medium” and “storage medium” should be taken to include a single medium or multiple media (e.g., a centralized/distributed database and/or associated caches and servers) that store one or more sets of instructions 628. The term “machine-readable medium” and “storage medium” shall also be taken to include any medium that is capable of storing, encoding, or carrying a set of instructions for execution by the processing system 600.

In general, the routines executed to implement the embodiments of the disclosure can be implemented as part of an operating system or a specific application, component, program, object, module, or sequence of instructions (collectively referred to as “computer programs”). The computer programs typically comprise one or more instructions (e.g., instructions 604, 608, 628) set at various times in various memory and storage devices in a computing device. When read and executed by the one or more processors 602, the instruction(s) cause the processing system 600 to perform operations to execute elements involving the various aspects of the disclosure.

Moreover, while embodiments have been described in the context of fully functioning computing devices, those skilled in the art will appreciate that the various embodiments are capable of being distributed as a program product in a variety of forms. The disclosure applies regardless of the particular type of machine or computer-readable media used to actually effect the distribution.

Further examples of machine-readable storage media, machine-readable media, or computer-readable media include recordable-type media such as volatile and non-volatile memory devices 610, floppy and other removable disks, hard disk drives, optical disks (e.g., Compact Disk Read-Only Memory (CD-ROMS), Digital Versatile Disks (DVDs)), and transmission-type media such as digital and analog communication links.

The network adapter 612 enables the processing system 600 to mediate data in a network 614 with an entity that is external to the processing system 600 through any communication protocol supported by the processing system 600 and the external entity. The network adapter 612 can include a network adaptor card, a wireless network interface card, a router, an access point, a wireless router, a switch, a multilayer switch, a protocol converter, a gateway, a bridge, bridge router, a hub, a digital media receiver, and/or a repeater.

The network adapter 612 can include a firewall that governs and/or manages permission to access/proxy data in a computer network and tracks varying levels of trust between different machines and/or applications. The firewall can be any number of modules having any combination of hardware and/or software components able to enforce a predetermined set of access rights between a particular set of machines and applications, machines and machines, and/or applications and applications (e.g., to regulate the flow of traffic and resource sharing between these entities). The firewall can additionally manage and/or have access to an access control list that details permissions including the access and operation rights of an object by an individual, a machine, and/or an application, and the circumstances under which the permission rights stand.

The techniques introduced here can be implemented by programmable circuitry (e.g., one or more microprocessors), software and/or firmware, special-purpose hardwired (i.e., non-programmable) circuitry, or a combination of such forms. Special-purpose circuitry can be in the form of one or more application-specific integrated circuits (ASICs), programmable logic devices (PLDs), field-programmable gate arrays (FPGAs), etc.

The techniques disclosed herein can include a tool or system to extract information from a design drawing to supplement the capabilities of a product manufacturing process. The present embodiments can assist in the generation/modification of a quote/estimate, the generation of manufacture feedback, the manufacturing scheduling/ordering process, etc.

### Remarks

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or” in reference to a list of two or more items covers all of the following interpretations of the word: any of the items in the list, all of the items in the list, and any combination of the items in the list.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

The above Detailed Description of examples of the invention is not intended to be exhaustive or to limit the invention to the precise form disclosed above. While specific examples for the invention are described above for illustrative purposes, various equivalent modifications are possible within the scope of the invention, as those skilled in the relevant art will recognize. For example, while processes or blocks are presented in a given order, alternative implementations may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed or implemented in parallel or may be performed at different times. Further any specific numbers noted herein are only examples: alternative implementations may employ differing values or ranges.

The teachings of the invention provided herein can be applied to other systems, not necessarily the system described above. The elements and acts of the various examples described above can be combined to provide further implementations of the invention. Some alternative implementations of the invention may include not only additional elements to those implementations noted above, but also may include fewer elements.

These and other changes can be made to the invention in light of the above Detailed Description. While the above description describes certain examples of the invention, and describes the best mode contemplated, no matter how detailed the above appears in text, the invention can be practiced in many ways. Details of the system may vary considerably in its specific implementation, while still being encompassed by the invention disclosed herein. As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific examples disclosed in the specification, unless the above Detailed Description section explicitly defines such terms. Accordingly, the actual scope of the invention encompasses not only the disclosed examples, but also all equivalent ways of practicing or implementing the invention under the claims.

I/We claim:

1. A computer-implemented method for automatically providing an estimated production value for a mechanical part, the computer-implemented method comprising:
obtaining an electronic illustration of a design of the mechanical part;
processing the electronic illustration to detect a depiction of the mechanical part and a portion of text included in the electronic illustration;
deriving a text pattern included in the portion of text included in the electronic illustration;
identifying a first classification of a series of classifications that corresponds to a type of information included in the text pattern;
processing the text pattern associated with the first classification using a rules engine, wherein the processing of the text pattern includes:
identifying a first rule of multiple rules in the rules engine that corresponds to the first classification; and
generating a modification value for the mechanical part based on information included in the first rule in the rules engine that corresponds to the first classification;
generating the estimated production value for the mechanical part that includes the modification value; and
providing the estimated production value for the mechanical part to a client computing device associated with a client.

2. The computer-implemented method of claim 1, further comprising:
deriving a first position for the depiction of the mechanical part and a second position for the portion of text included in the electronic illustration; and
associating the text pattern with the depiction of the mechanical part based on determining that the first position of the depiction of the mechanical part is within a threshold proximity of the second position of the portion of text,
wherein the first classification is identified based on the association between the text pattern and the depiction of the mechanical part.

3. The computer-implemented method of claim 1, further comprising:
generating an initial production value indicative of an initial value to manufacture the mechanical part based on inspecting only the depiction of the mechanical part, wherein the estimated production value modifies the initial production value based on the modification value.

4. The computer-implemented method of claim 1, wherein deriving the text pattern further comprises:
deriving a text type of each character in the portion of text included in the electronic illustration; and
combining characters in the portion of text of a common text type, wherein the combined characters of the common text type are included as part of the text pattern.

5. The computer-implemented method of claim 4, further comprising:
comparing a first character comprising a symbol text type in the portion of text with a table indicative of symbol definitions to derive a first definition of the first character; and
identifying a series of characters of various text types, the series of characters including the first character and a second set of characters of another text type, wherein the series of characters are included as part of the text pattern and are utilized in classifying the text pattern.

6. The computer-implemented method of claim 1, wherein processing the text pattern associated with the first classification using the rules engine further includes:
comparing a condition associated with the first rule with the text pattern to determine whether the text pattern satisfies the condition associated with the first rule; and
responsive to determining that the text pattern satisfies the condition associated with the first rule, applying the first rule to the depiction of the mechanical part to generate the modification value.

7. The computer-implemented method of claim 1, wherein deriving the text pattern included in the portion of text included in the electronic illustration includes:
processing the portion of text with a series of regular expressions to derive a pattern in the portion of text, the pattern included in the text pattern.

8. The computer-implemented method of claim 1, further comprising:
determining that the text pattern does not match any classification in the series of classifications; and
generating an alert message indicating that the text pattern includes information that is beyond information included in the series of classifications.

9. The computer-implemented method of claim 1, wherein providing the estimated production value for the mechanical part to the client device associated with the client further includes:
generating a line-item report that includes multiple line items indicative of modifications to the depiction of the mechanical part based on the text pattern, the line-item report including the estimated production value, the modification value, and a description of the first rule in the rules engine that corresponds to the first classification.

10. The computer-implemented method of claim 1, further comprising:
identifying an indicator associated with the portion of text;
determining that a direction of the indicator that identifies a region of the depiction of the mechanical part; and
associating the portion of text with the region of the depiction of the mechanical part based on the direction of the indicator.

11. A method comprising:
obtaining an electronic illustration of a component to be manufactured;
identifying a first depiction of the component and a first text string included in the electronic illustration;
generating an initial value indicative of a value to manufacture the component based on automatically inspecting the first depiction of the component;
identifying a first classification, from a series of classifications, that corresponds to a first type of information included in the first text string;
processing the first text string associated with the first classification to identify a first rule of multiple rules that corresponds to the first classification;
generating a first modification value to modify for the component based on information included in the first rule that corresponds to the first classification;
generating an estimated production value for the component that includes the initial value modified by the first modification value; and
providing the estimated production value for the component to a client device associated with a client.

12. The method of claim 11, further comprising:
identifying a second depiction of the component and a second text string included in the electronic illustration, the second depiction of the component illustrating a perspective of the component that is different than another perspective illustrated in the first depiction of the component;
identifying a second classification of the set of classifications that corresponds to a second type of information included in the second text string;
processing the second text string associated with the second classification to identify a second rule of multiple rules that corresponds to the second classification;
generating a second modification value to modify the estimated production value for the component based on information included in the second rule; and
updating the estimated production value based on the second modification value.

13. The method of claim 11, further comprising:
deriving a first position for the first depiction of the component and a second position for the first text string included in the electronic illustration; and
associating the first text string with the first depiction of the component based on determining that the first position of the first depiction of the component is within a threshold proximity of the second position of the first text string,
wherein the first classification is identified based on the association between the first text string and the first depiction of the component.

14. The method of claim 11, wherein deriving the first text string further comprises:
deriving a text type of each character in the first text string included in the electronic illustration;
combining characters in the first text string of a common text type, wherein the combined characters of the common text type are included as part of the first text string.

15. The method of claim 11, wherein processing the first text string associated with the first classification further includes:
comparing a condition associated with the first rule with the first text string to determine whether the first text string satisfies the condition associated with the first rule; and
responsive to determining that the first text string satisfies the condition associated with the first rule, applying the first rule to the first depiction of the component to generate the first modification value.

16. A non-transitory machine-readable medium having machine executable instructions stored thereon that, when executed by one or more processors, direct the one or more processors to perform a method for automatically providing an estimate for manufacturing a mechanical part, the method comprising:
obtaining an image file of a mechanical part to be manufactured;
processing the image file to detect a depiction of the mechanical part and text included in the image file;
deriving a text pattern included in the text included in the image file;
identifying a first classification of a set of classifications that corresponds to a type of information included in the text pattern;
processing the text pattern associated with the first classification using a rules engine, including:
identifying a first rule of multiple rules in the rules engine that corresponds to the first classification; and
generating a modification value for the mechanical part based on information included in the first rule in the rules engine that corresponds to the first classification;
generating an estimate for manufacturing the mechanical part that includes the modification value; and
providing the estimate for the mechanical part to a client device.

17. The non-transitory machine-readable medium of claim 16, further comprising:
deriving a first position for the depiction of the mechanical part and a second position for the text included in the image file; and
associating the text pattern with the depiction of the mechanical part based on determining that the first position of the depiction of the mechanical part is within a threshold proximity of the second position of the text,
wherein the first classification is identified based on the association between the text pattern and the depiction of the mechanical part.

18. The non-transitory machine-readable medium of claim 16, wherein deriving the text pattern further comprises:
deriving a text type of each character in the text included in the image file;
combining characters in the text of a common text type, wherein the combined characters of the common text type are included as part of the text pattern;
comparing a first character comprising a symbol text type in the text with a table indicative of symbol definitions to derive a first definition of the first character; and
identifying a set of characters of various text types, the set of characters including the first character and a second set of characters of another text type, wherein the set of characters are included as part of the text pattern and are utilized in classifying the text pattern.

19. The non-transitory machine-readable medium of claim 16, wherein providing the estimated production value for the mechanical part to the client device associated with the client further includes:
generating a line-item report that includes multiple line items indicative of modifications to the depiction of the mechanical part based on the text pattern, the line-item report including the estimated production value, the modification value, and a description of the first rule in the rules engine that corresponds to the first classification.

20. The non-transitory machine-readable medium of claim 16, further comprising:
identifying an indicator associated with the;
determining that a direction of the indicator that identifies a region of the depiction of the mechanical part; and
associating the text with the region of the depiction of the mechanical part based on the direction of the indicator.
